(19) United States
(12) Patent Application Publication
(10) Pub. No.: US 2009/0140774 A1
(43) Pub. Date: Jun. 4, 2009

(54) SYSTEM AND METHOD FOR COMMUNICATING DATA AMONG CHAINED CIRCUITS

(76) Inventors: Jeff Kotowski, Nevada City, CA (US); Shane Hollmer, Grass Valley, CA (US)

Correspondence Address: Zilka-Kotab, PC, P.O. BOX 721120, SAN JOSE, CA, 95172-1120, US

(21) Appl. No.: 11/949,626

(22) Filed: Dec. 3, 2007

(51) Int. Cl. G01R 23/02

(52) U.S. Cl. 327/47

(57) ABSTRACT

A system and method are provided for communicating data among chained circuits. In operation, a period of a signal communicated between a chain of circuits is identified. Additionally, a state of the signal is determined, based on the period of the signal.

### FIELD OF THE INVENTION

The present invention relates to circuit chains, and more particularly to communicating data among chained circuits.

### BACKGROUND

Single-pin serial data links typically employ a single data wire for communicating data among circuits, while using a common clock for sampling purposes. During use, a small delay may be incurred at each of the aforementioned circuits. In situations where a large number of such circuits are chained (particularly where the circuits are separated by large distances), such delay may aggregate to the point of making the data link inoperable.

In some serial data links, pulse width modulation (PWM) is used to determine a state of a signal based on modulation of a signal duty cycle. However, with non-equal rise and fall times and a non-equal delay length across the circuits, pulse widths tend to shift from circuit to circuit. Again, when a large number of such circuits are chained, it is conceivable that the duty cycle may go to zero. While such problem may be addressed utilizing a phase locked loop (PLL), such circuitry would inevitably contribute to the cost of any resultant design.

Additionally, the single data wire used for communicating data among the circuits has inherent resistive characteristics, which leads to a voltage offset between sequential circuits in a chain. This voltage offset is cumulative through the chain of circuits. Therefore, circuits towards the end of the chain often experience large voltage offsets a result of this cumulative effect.

There is thus a need for addressing these and/or other issues associated with the prior art.

### SUMMARY

A system and method are provided for communicating data among chained circuits. In operation, a period of a signal communicated between a chain of circuits is identified. Additionally, a state of the signal is determined, based on the period of the signal.

### BRIEF DESCRIPTION OF THE DRAWINGS

FIG. 1 shows a method for communicating data among chained circuits, in accordance with one embodiment.

FIG. 2 shows a signal for communication among chained circuits, in accordance with one embodiment.

FIG. 3 shows a frame of data for communication among chained circuits, in accordance with one embodiment.

FIG. 4 shows a system for communicating data among chained circuits, in accordance with another embodiment.

FIG. 5 shows a system for communicating data among chained circuits, in accordance with another embodiment.

FIG. 6 shows a system for implementing a latched counter, in accordance with one embodiment.

### DETAILED DESCRIPTION

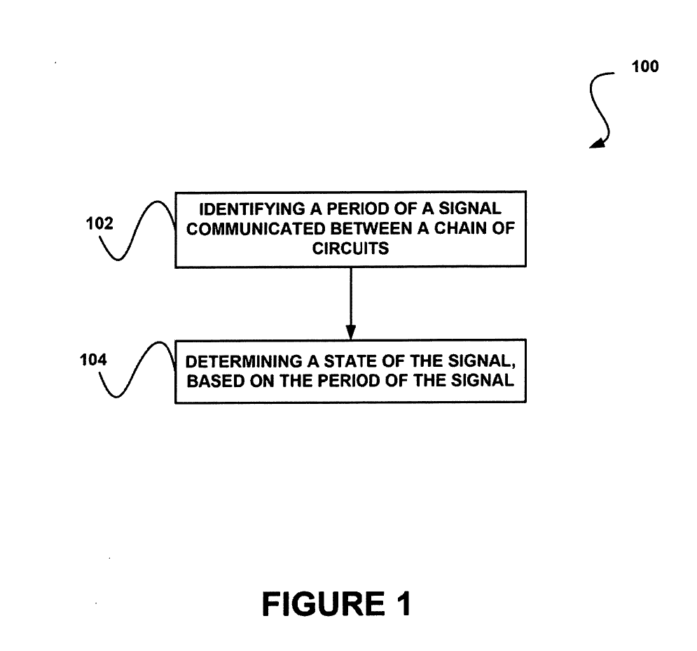

FIG. 1 shows a method 100 for communicating data among chained circuits, in accordance with one embodiment. As shown, a period of a signal communicated between a chain of circuits is identified. See operation 102. In the context of the present description, a signal refers to any signal or data communicated between a chain of circuits.

Further, in the context of the present description, chained circuits refer to one or more circuits that are in communication with another circuit. Additionally, the chained circuits may include any type of circuits. For example, in various embodiments, the chained circuits may include digital circuits, analog circuits, integrated circuits, asynchronous circuits, and/or any other type of circuits, for that matter.

Furthermore, the circuits may include circuits used in any application that are able to use circuits in a chain. For example, in various embodiments, such circuits may include, but are not limited to circuits for use in industrial applications, display applications (e.g. pixel displays, pixel drivers, etc.), lighting applications (e.g. car lighting, interior lighting, exterior lighting, etc.), control system applications (e.g. conveyors, safety devices, door locks, etc.), and or/any applications that may use circuits in a chain.

Additionally, the chain of circuits may include any circuits linked in a chain format. For example, in one embodiment, the chain of circuits may include a daisy chain. As an option, the chain of circuits may include a serial data link. In this case, the signal may be communicated utilizing the serial data link.

As another option, the signal may be communicated utilizing a single data wire. In this case, each circuit may include only one connector for the single data wire. Of course, any number wires and/or connectors may be used depending on the application.

Strictly as an option, the period of the signal may be identified based on a first and a second rising edge of the signal. As another option, the period of the signal may be identified based on a first and a second falling edge of the signal. Additionally, a state of the signal is determined, based on the period of the signal. See operation 104.

In one embodiment, the state of the signal may be ascertained from a duration of the period of the signal. In this case, the duration of the period may correspond to the state. For example, a first predetermined duration may represent a high state (e.g. a “1”). Additionally, a second predetermined duration may represent a low state (e.g. a “0”). In one embodiment, a first predetermined duration may represent a state and any duration other than the first predetermined duration may represent another state.

More illustrative information will now be set forth regarding various optional architectures and features with which the foregoing framework may or may not be implemented, per the desires of the user. For example, in various embodiments to be described, the aforementioned design may allow the state to be determined independent of a ground and/or power supply offset, a delay in rise time and/or fall time, etc. Further, a cost of implementation may be reduced, in some embodiments [e.g. by avoiding the requirement of a phase locked loop (PLL), etc.]. It should be strongly noted that the following information is set forth for illustrative purposes and should not be construed as limiting in any manner. Any of the following features may be optionally incorporated with or without the exclusion of other features described.

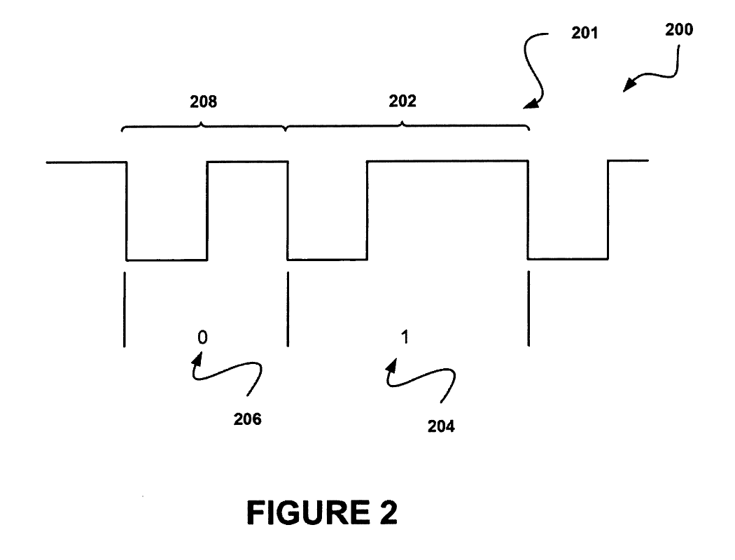

FIG. 2 shows a signal 200 for communication among chained circuits, in accordance with one embodiment. As an option, the signal 200 may be embodied in the context of the method 100 of FIG. 1. Of course, however, the signal 200 may be embodied in any desired environment. It should also be noted that the aforementioned definitions may apply during the present description.

As shown, a period 201 of the signal 200 is identified. In operation, the signal 200 is communicated between a chain of circuits. Furthermore, a state 204 of the signal 200 is determined, based on the period 202 of the signal 200.

In this case, a duration of the period 201 may correspond to the state 204 of the signal 200. As an option, a first predetermined duration may represent a high state 204 and a second predetermined duration may represent a low state 206. As a specific example, a short period 208 (e.g. a short bit time) may correspond to the low state 206 (i.e. “0”).

In one specific case, a short period 208 may be measured falling edge to falling edge (e.g. as 250 nS). On the other hand, a long period 202 (e.g. a long bit time) may correspond to the high state 204 (i.e. “1”). In this case, the long period 202 may be measured falling edge to falling edge (e.g. as 500 nS). Thus, a longer period may correspond to a high state and a shorter period may correspond to a low state.

Of course, in another embodiment, a longer period may correspond to a low state and a shorter period may correspond to a high state. Additionally, a long and short period may be defined using any duration depending on the application. Furthermore, the short period may be any time and is not limited to 50% of the long period. For example, in another embodiment, the short period may be 125 nS, etc. (instead of 250 nS, as set forth above).

In one embodiment, the period (e.g. a bit time) may be measured by switching a current source input to a capacitor, to yield a reference voltage. In another embodiment, the period may be measured using a latched counter clocked at a higher speed. Strictly as an option, the latched counter may be counter clocked at a speed of approximately ten times the data rate of the signal 200.

In operation, high bits (e.g. “1's”) and low bits (e.g. “0's”) may be sent in a period (e.g. falling edge to falling edge, or rising edge to rising edge) to the chained circuits. As an option, the chained circuits may be enabled when a first predetermined state occurs for at least a threshold duration. Further, the circuits may be disabled when a second predetermined state occurs for at least the threshold duration.

Such thresholds may be predetermined thresholds, for example. In various embodiments, the threshold durations may vary. In one embodiment, a static high may enable the circuits and a static low may disable the circuits. In this case, both the static high and static low may enable and disable the circuits when the static signals occur for at least a threshold duration.

As an option, the threshold duration for the static high and the static low may be different values. Additionally, in another embodiment, a static low may enable the circuits. In such embodiment, a static high may disable the circuits.

As another option, the chained circuits may include a fixed frequency data link. In this case, data communicated to the chained circuits may have a fixed frequency. Thus, the period of the data signal may be identified based on the fixed frequency.

In another embodiment, the data communicated to the chained circuits may include a plurality of sequential frames of data. In this case, each circuit may take a first frame of data in the sequential frames of data. The remaining frames of data may then be passed to subsequent circuits in the chain of circuits, where the next circuit takes the first frame of data in the remaining frames of data, etc.

In still another embodiment, the frame of data taken for each circuit may be stored in a buffer corresponding to the circuit. In such embodiment, the data for each circuit may be synchronously latched. In another embodiment, the frame of data taken for each circuit may be latched asynchronously.

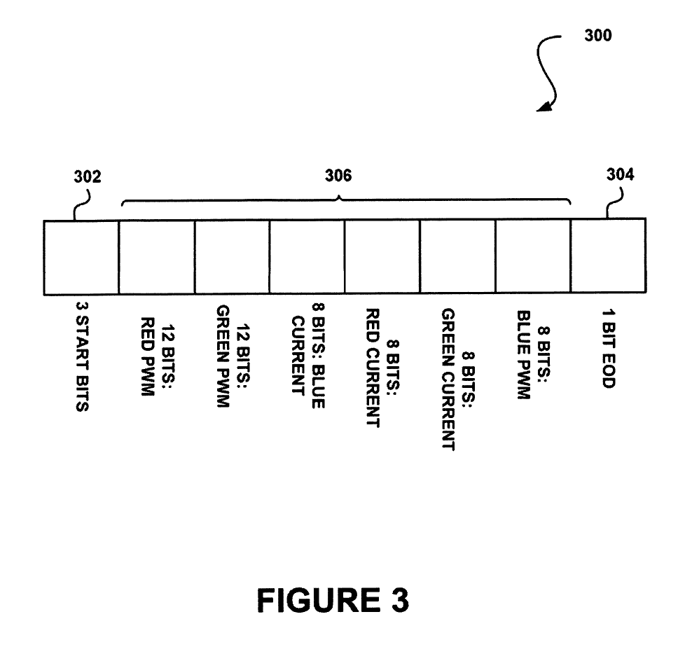

FIG. 3 shows a frame of data 300 for communication among chained circuits, in accordance with one embodiment. As an option, the frame of data 300 may be embodied in the context of the functionality and architecture of FIGS. 1-2. Of course, however, the frame of data 300 may be embodied in any desired environment. Again, the aforementioned definitions may apply during the present description.

As shown, three start bits 302 (e.g. of logic “1”) synchronize the frame of data 300 (e.g. synchronize a bit time, etc.). Additionally, an end of data (EOD) bit 304 is provided to indicate the end of the frame of data 300. The EOD bit 304 allows a long segment to cleanly enable the data at the output of one circuit when the output begins sending a subsequent frame of data to subsequent circuits in a circuit chain. In one specific embodiment where the data 300 is used to drive display pixels or the like, data bits 306 are provided which include 12 bits of red PWM, 12 bits of green PWM, 12 bits of blue PWM, 8 bits of red color correction (e.g. sets current color), 8 bits green color correction, and 8 bits blue color correction for a total of 64 bits in the frame of data 300.

In operation, the frame of data 300 may be data embodied on a signal. In this case, the signal may be communicated between a chain of circuits. Thus, a period of the signal may be identified and a state of the signal may be determined based on the period of the signal. In the above example, the frame of data 300 may serve as an input to circuits that work in conjunction with one of a plurality of display pixels. As an option, the circuits may include pixel drivers.

It should be noted that the specific frame of data 300 of FIG. 3 is merely set forth for illustrative purposes and should not be construed as limiting in any manner. In various embodiments, the frame of data 300 may include any number of start bits 302 and/or data bits 306. For example, in one embodiment the frame of data 300 may include one start bit 302 and N data bits 306. In this case, the N data bits may be made up of any number of address and/or data bits.

Additionally, the frame of data 300 may include any number of EOD bits 304. In one embodiment, the frame of data 300 may not include any EOD bits 304. In this case, N data bits 306 may correspond to the end of data.

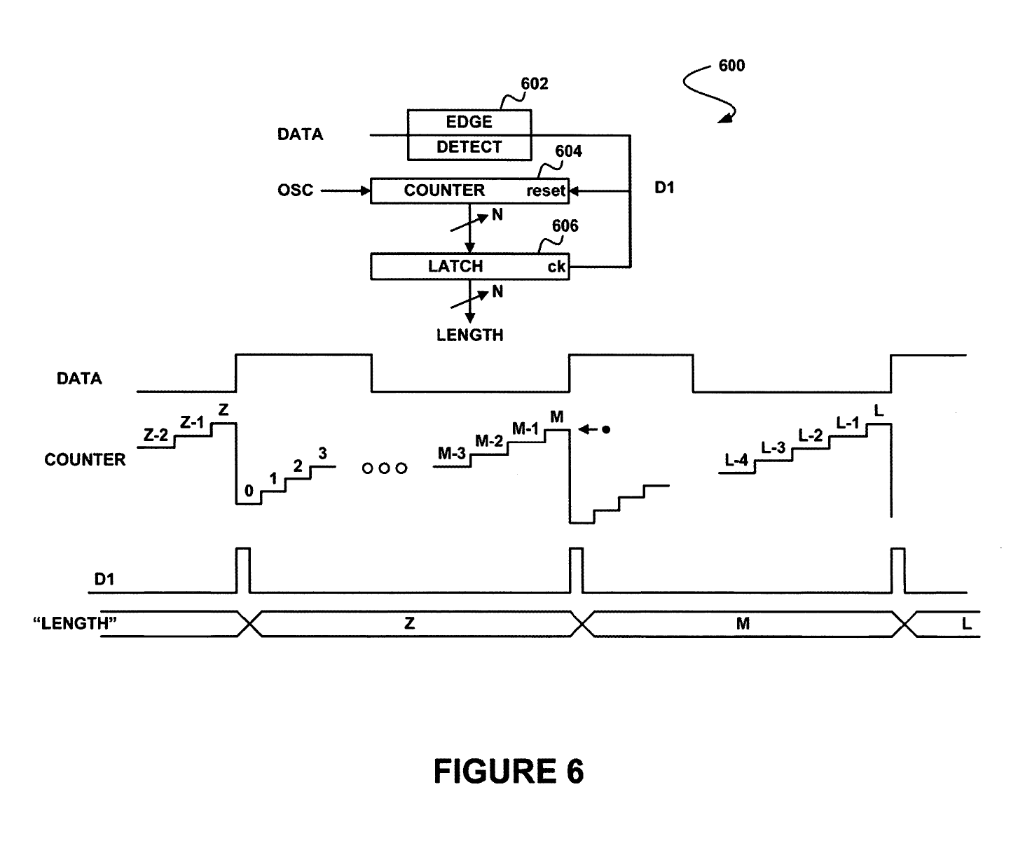

In one embodiment, the start bits 302 may be used to measure the frame length. As an option, the start bits 302 may be used to round the frame length to a power of two. In another embodiment, the period time or bit time may be measured by switching a current source into a capacitor, to yield a reference voltage. In another embodiment, the period time or bit time may be measured using a latched counter clocked at a higher speed. Strictly as an option, the latched counter may be counter clocked at a speed approximately ten times the data rate. More information regarding the use of a latched counter clocked at a higher speed is discussed below in the context of the details of FIG. 6.

In one embodiment, the data bits may be stored in the length of a pulse (i.e. pulse timing). In another embodiment, edge-to-edge timing may be utilized. In still another embodiment, both edge-to-edge timing and pulse timing may be implemented by using a constant low or constant high time.

As an option, a variable bit length may be utilized for the start bit 302, data bits 306, and/or EOD bit 304. Additionally, in the case that the data communicated to the chained circuits has a fixed frequency, the start bit 302 may be omitted. Similarly, the EOD bit 304 may be omitted.

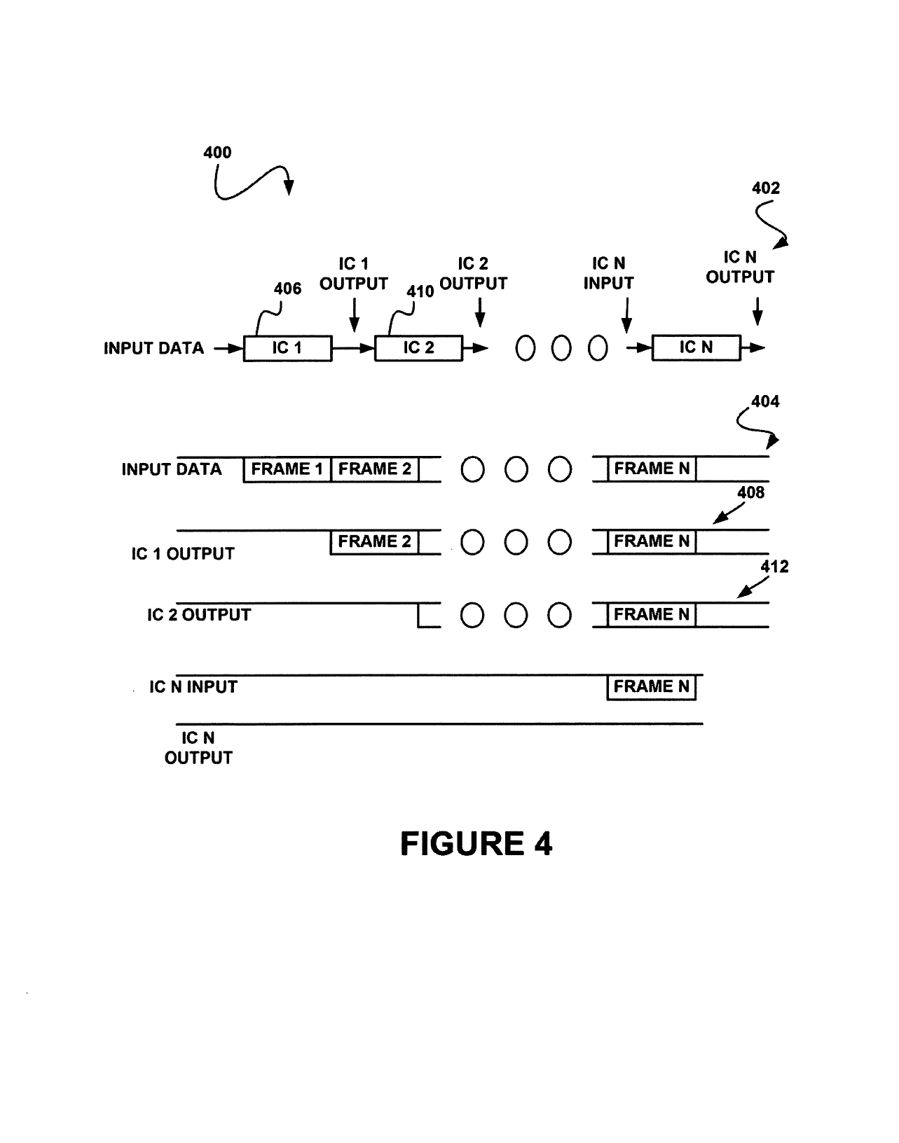

FIG. 4 shows a system 400 for communicating data among chained circuits, in accordance with another embodiment. As an option, the system 400 may be implemented in the context of the functionality and architecture of FIGS. 1-3. Of course, however, the system 400 may be implemented in any desired environment. It should also be noted that the aforementioned definitions may apply during the present description.

As shown, a daisy chain of integrated circuits 402 is provided. In operation, input data 404 is input to a first integrated circuit 406. A first frame of data of the input data 404 is taken by the first integrated circuit 406. An output 408 of the first integrated circuit 406 serves as an input to a second integrated circuit 410. The second integrated circuit 410 then takes a second frame of data, although from the perspective of the integrated circuit 410 the frame of data is the first set of data because the first integrated circuit 406 stripped off the original first frame of data. An output 412 of the second integrated circuit 410 serves as an input for a subsequent integrated circuit in the chain of integrated circuits 402.

In one embodiment, the first frame of data and the second frame of data may have the same number of bits. As an option, the input data 404 may include a predetermined format. In another embodiment, the first frame of data and the second frame of data may have a different number of bits.

Additionally, in one embodiment, the frame data corresponding to each integrated circuit in the chain of integrated circuits 402 may be latched at the same time. In this case, the frame data corresponding to each integrated circuit may be buffered through each integrated circuit. Thus, once the input data 404 ends or the data stops (e.g. a bit is held high, etc.), all of the integrated circuits 402 may detect the end of the data and use such data at the same time (plus or minus some small buffering delays and latch time differences).

As an option, the integrated circuits 402 may be disabled when the input data switches to zero. The disable signal may transfer through each integrated circuit 402. In one embodiment, the disable signal may be a low signal. In various embodiments, the disable signal may be configured as a synchronous or an asynchronous signal.

For example, a synchronous operation for shutdown may be implemented by writing a zero PWM to each integrated circuit 402, latching in this state, and subsequently utilizing a data low signal to disable the integrated circuits 402. Of course, in other embodiments, the integrated circuits 402 may be disabled using various disable signals. It should be noted that, although the circuits in the chain of circuits are illustrated as integrated circuits 402, such circuits may be any type of circuits. For example, in various other embodiments such circuits may include any type of digital and/or analog circuits.

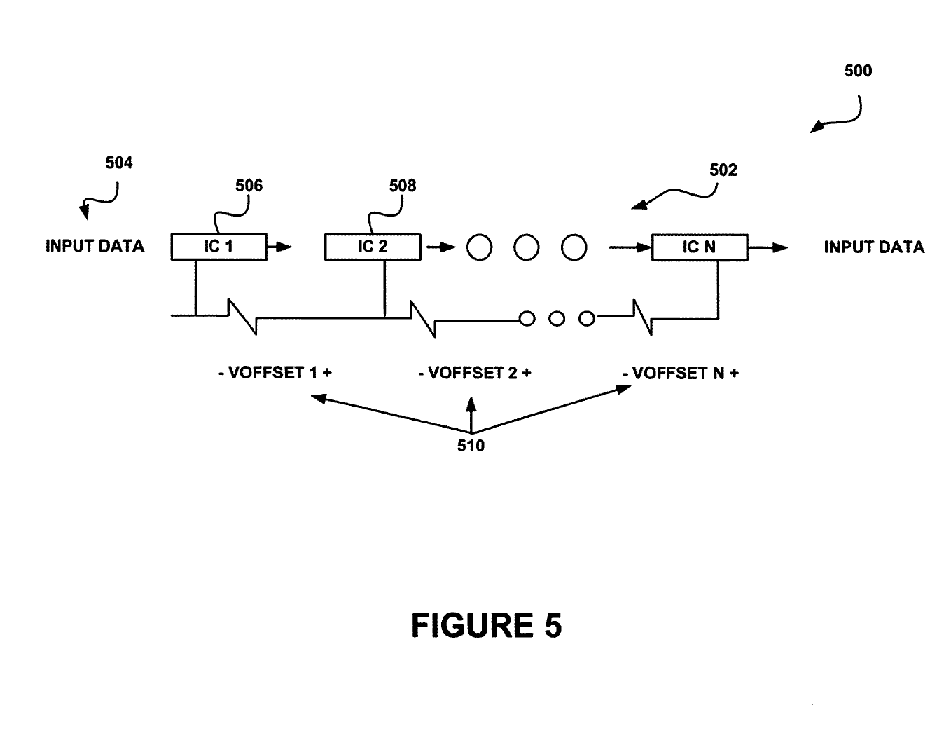

FIG. 5 shows a system 500 for communicating data among chained circuits, in accordance with another embodiment. As an option, the present system 500 may be implemented in the context of the functionality and architecture of FIGS. 1-4. Of course, however, the system 500 may be implemented in any desired environment. Yet again, the aforementioned definitions may apply during the present description.

As shown, a daisy chain of integrated circuits 502 is provided. In operation, input data 504 is an input signal to a first integrated circuit 506. In this case, first data embodied on the signal is stored by the first integrated circuit 506 and removed from the signal. Second data embodied on the signal subsequent the first data is then stored by a second integrated circuit 508 and removed from the signal.

Additionally, a period of the signal communicated between the daisy chain of integrated circuits 502 is identified. Using the period, a state of the signal is determined. It should be noted that the state may be determined independent of a ground offset and/or a power supply offset (e.g. see offsets 510).

In this case, when ground currents create offsets, buffering of the input data 504 shifts each output to a new offset ground. Thus, each integrated circuit only experiences a small offset from circuit to circuit. For example, as a signal is communicated through the first integrated circuit 506, the signal may receive an offset (e.g. 20 mV) as a result of wire resistance.

However, the output of the signal from the first integrated circuit 506 is reset such that a second integrated circuit 508 experiences the offset from only the first integrated circuit 506. In this manner, integrated circuits following multiple integrated circuits may only experience voltage offsets from the previous integrated circuit. Thus, the voltage offset is not necessarily cumulative through the chain of circuits.

FIG. 6 shows a system 600 for implementing a latched counter, in accordance with one embodiment. As an option, the present system 600 may be implemented in the context of the functionality and architecture of FIGS. 1-5. Of course, however, the system 600 may be implemented in any desired environment. Additionally, the aforementioned definitions may apply during the present description.

As shown, an edge detect circuit 602, a latch 604, and a counter 606 are provided. In this case, the output “length” indicates the length of a pulse (from edge to edge) in units of the oscillator time period. In operation, the edge detect 602 creates a short pulse “D1.” This pulse latches the counter value from the last count. The counter 606 in then reset to start counting the next period. In this way, a period time or bit time may be measured as noted above.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

What is claimed is:

1. A method, comprising:
identifying a period of a signal communicated between a chain of circuits; and
determining a state of the signal, based on the period of the signal.

2. The method of claim 1, wherein the chain of circuits includes a daisy chain.

3. The method of claim 1, wherein the chain of circuits includes a serial data link.

4. The method of claim 1, wherein the circuits include integrated circuits.

5. The method of claim 1, wherein the signal is communicated utilizing a single data wire.

6. The method of claim 1, wherein the period is identified based on a first rising edge and a second rising edge of the signal.

7. The method of claim 1, wherein the period is identified based on a first falling edge and a second falling edge of the signal.

8. The method of claim 1, wherein a first predetermined duration represents a high state.

9. The circuit of claim 8, wherein a second predetermined duration represents a low state.

10. The method of claim 1, wherein first data embodied on the signal is stored by a first circuit and removed from the signal, after which second data embodied on the signal subsequent the first data is stored by a second circuit and removed from the signal.

11. The circuit of claim 10, wherein the first data and the second data have the same number of bits.

12. The method of claim 1, wherein data embodied on the signal includes a predetermined format.

13. The method of claim 12, wherein the data includes one or more beginning bits that are used for synchronization purposes.

14. The method of claim 1, wherein the signal has a fixed frequency.

15. The method of claim 1, wherein the circuits are enabled when a first predetermined state occurs for at least a threshold duration.

16. The method of claim 15, wherein the circuits are disabled when a second predetermined state occurs for at least the threshold duration.

17. The method of claim 1, wherein the state is determined independent of at least one of a ground offset and a power supply offset.

18. The method of claim 1, wherein the state is determined independent of a delay in at least one of a rise time and a fall time.

19. The method of claim 1, wherein each of the circuits works in conjunction with one of a plurality of display pixels.

20. The method of claim 19, wherein the circuits include pixel drivers.

21. A system, comprising:
a chain of circuits for communicating utilizing a protocol that: identifies a period of a signal communicated between the chain of circuits, and determines a state of the signal, based on the period of the signal.

22. An apparatus, comprising:
a circuit capable of communicating with other circuits utilizing a protocol that: identifies a period of a signal communicated between the chain of circuits, and determines a state of the signal, based on the period of the signal.
